(19) United States
(12) Patent Application Publication
(10) Pub. No.: US 2011/0316035 A1
(43) Pub. Date: Dec. 29, 2011

(54) HEAT DISSIPATING SUBSTRATE AND METHOD OF MANUFACTURING THE SAME

(75) Inventors: Sang Hyun Shin, Gyunggi-do (KR); Tae Hoon Kim, Gyunggi-do (KR); Cheol Ho Heo, Busan (KR); Young Ki Lee, Gyunggi-do (KR); Ji Hyun Park, Seoul (KR); Ki Ho Seo, Gyunggi-do (KR)

(73) Assignee: SAMSUNG ELECTRO-MECHANICS CO., LTD., Gyunggi-do (KR)

(21) Appl. No.: 12/897,936

(22) Filed: Oct. 5, 2010

(30) Foreign Application Priority Data
Jun. 23, 2010 (KR) 1020100059441

(51) Int. Cl. H01L 33/48; H01L 33/64

(52) U.S. Cl. 257/99; 438/26; 257/E33.056; 257/E33.075

(57) ABSTRACT

Disclosed is a heat-dissipating substrate, which includes a base substrate including a metal layer, an insulating layer formed on one surface of the metal layer, and a circuit layer formed on the insulating layer, a heat sink layer formed on the other surface of the metal layer, a connector for connecting the base substrate and the heat sink layer to each other, an opening formed in a direction of thickness of the base substrate and into which the connector is inserted, and an anodized layer formed on either or both of the other surface and a lateral surface of the metal layer, and in which the metal layer and the heat sink layer are insulated from each other by means of the anodized layer, thus preventing transfer of static electricity or voltage shock to the metal layer. A method of manufacturing the heat-dissipating substrate is also provided.

### CROSS REFERENCE TO RELATED APPLICATION

This application claims the benefit of Korean Patent Application No. 10-2010-0059441, filed Jun. 23, 2010, entitled “Heat-radiating substrate and manufacturing method thereof”, which is hereby incorporated by reference in its entirety into this application.

### BACKGROUND OF THE INVENTION

1. Technical Field

The present invention relates to a heat-dissipating substrate and a method of manufacturing the same.

2. Description of the Related Art

In order to solve heat dissipation problems of power devices and power modules recently used in various fields, a lot of effort is directed to manufacturing heat-dissipating substrates in various forms using metal materials having high thermal conductivity. At the same time, heat-dissipating substrates having a multilayered micropattern are required not only in light-emitting diode (LED) modules and power modules but also in the other products.

However, conventional organic printed circuit boards, ceramic substrates, glass substrates or heat-dissipating substrates including metal core layers are disadvantageous because it is relatively difficult to form a micropattern and the manufacturing cost thereof is higher, compared to silicone wafers, and thus the applications thereof are limited. Accordingly, research into heat-dissipating substrates which use anodizing treatment to maximize heat dissipation from heating devices is presently ongoing.

A conventional method of manufacturing a heat-dissipating substrate is illustratively described below.

First, anodizing treatment is performed on one surface of a metal layer thus forming an insulating layer thereon.

Next, a copper foil is formed on the insulating layer and is then patterned, thus forming a circuit layer. Alternatively, a patterned circuit layer may be formed using a plating process.

Next, a heat sink is connected to the other surface of the metal layer on which the insulating layer is not formed, and a heating device electrically connected to the circuit layer is mounted on the insulating layer.

Because the conventional heat-dissipating substrate has the large transfer effect of metal, heat generated from the heating device is dissipated to the outside via the metal layer and the heat sink. Hence, as the heating device formed on the heat-dissipating substrate is not subjected to high heat, problems of performance of the heating device deteriorating can be solved.

However, in the case of the conventional heat-dissipating substrate, because both the metal layer and the heat sink are made of a metal having electrical conductivity, an unexpected electrical connection may be formed between the metal layer and the heat sink. Thus, when static electricity or voltage shock occurs from the heat sink or the contact interface between the heat sink and the metal layer, it is directly transferred to the metal layer and thereby affects the circuit layer of the heat-dissipating substrate or the heating device, undesirably deteriorating the performance thereof.

### SUMMARY OF THE INVENTION

Accordingly, the present invention has been made keeping in mind the problems encountered in the related art and the present invention is intended to provide a heat-dissipating substrate which maintains heat dissipation properties and prevents the transfer of static electricity or voltage shock to a metal layer and a device, and also to provide a method of manufacturing the same.

An aspect of the present invention provides a heat-dissipating substrate, including a base substrate including a metal layer, an insulating layer formed on one surface of the metal layer, and a circuit layer formed on the insulating layer, a heat sink layer formed on the other surface of the metal layer, a connector for connecting the base substrate and the heat sink layer to each other, an opening formed in a direction of thickness of the base substrate and into which the connector is inserted, and an anodized layer formed on either or both of the other surface and a lateral surface of the metal layer.

In this aspect, the anodized layer may be further formed on an inner surface of the opening.

In this aspect, the insulating layer may be formed by anodizing the metal layer or by mixing epoxy with a ceramic filler.

In this aspect, the metal layer may include aluminum, and the insulating layer may include alumina formed by anodizing the metal layer.

In this aspect, the metal layer may include aluminum, and the anodized layer may include alumina formed by anodizing the metal layer.

In this aspect, a device mounted on the base substrate may be further included.

As such, the device may be an LED package.

Another aspect of the present invention provides a method of manufacturing a heat-dissipating substrate, including (A) forming an insulating layer on one surface of a metal layer and forming a circuit layer on the insulating layer, thus preparing a base substrate, (B) forming an opening in a direction of thickness of the base substrate, (C) forming an anodized layer on either or both of the other surface and a lateral surface of the metal layer, and (D) inserting a connector into the opening, thus connecting a heat sink layer to the other surface of the metal layer.

In this aspect, in (C) the anodized layer may be further formed on an inner surface of the opening.

In this aspect, in (A) the insulating layer may be formed by anodizing the metal layer or by mixing epoxy with a ceramic filler.

In this aspect, (A) may include (A1) providing a metal layer comprising aluminum, (A2) anodizing the metal layer, thus forming an insulating layer comprising alumina on the metal layer, and (A3) forming a circuit layer on the insulating layer, thus preparing a base substrate.

In this aspect, the metal layer may include aluminum, and the anodized layer may include alumina formed by anodizing the metal layer.

In this aspect, mounting a device on the base substrate may be further included, before or after (D).

The device may be an LED package.

A further aspect of the present invention provides a method of manufacturing a heat-dissipating substrate, including (A) preparing a substrate strip including a plurality of base substrates including a metal layer, an insulating layer formed on one surface of the metal layer, and a circuit layer formed on the insulating layer, (B) forming an opening in a direction of thickness of each of the base substrates, (C) cutting the substrate strip so that each of the base substrates is set off from the substrate strip, except for bridges for connecting the base substrates with the substrate strip, (D) forming an anodized layer on either or both of the other surface and a lateral surface of the metal layer, (E) removing the bridges, thus individually separating the base substrates, and (F) inserting a connector into the opening, thus connecting a heat sink layer to the other surface of the metal layer.

In this aspect, in (D) the anodized layer may be further formed on an inner surface of the opening.

In this aspect, in (A) the insulating layer may be formed by anodizing the metal layer or by mixing epoxy with a ceramic filler.

In this aspect, mounting a device on the base substrate may be further included, before or after (F).

The device may be an LED package.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a heat-dissipating substrate according to an embodiment of the present invention;

FIGS. 2 to 6 are views showing a process of manufacturing a heat-dissipating substrate according to a first embodiment of the present invention; and

FIGS. 7A and 7B to 11A and 11B and FIGS. 12 and 13 are views showing a process of manufacturing a heat-dissipating substrate according to a second embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar constituents. Furthermore, descriptions of known techniques, even if they are pertinent to the present invention, are regarded as unnecessary and may be omitted in so far as they would make the characteristics of the invention unclear and render the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

Heat-Dissipating Substrate

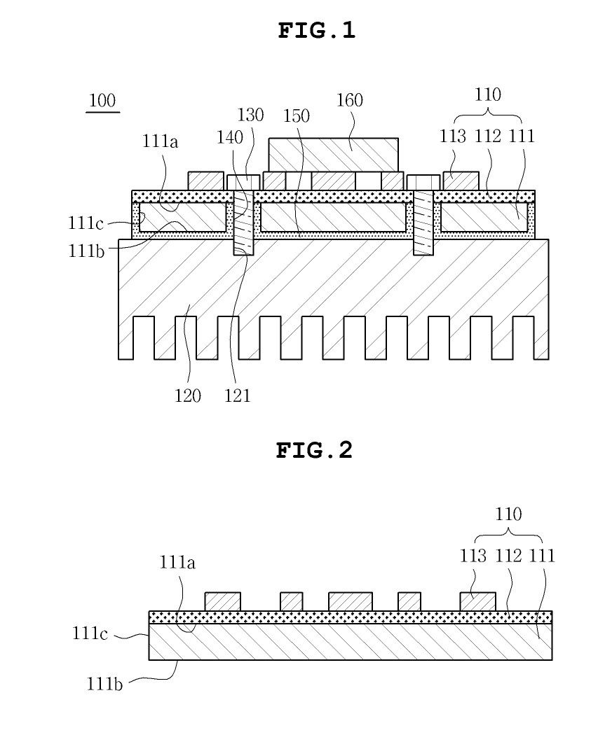

FIG. 1 is a cross-sectional view showing a heat-dissipating substrate 100 according to an embodiment of the present invention. With reference to this drawing, the heat-dissipating substrate 100 according to the present embodiment is described below.

As shown in FIG. 1, the heat-dissipating substrate 100 according to the present embodiment includes a base substrate 110 including a metal layer 111, an insulating layer 112 formed on one surface of the metal layer 111, and a circuit layer 113, openings 140 formed in the base substrate 110, a heat sink layer 120, connectors 130 inserted into the openings 140 so that the base substrate 110 and the heat sink layer 120 are connected to each other, and an anodized layer 150 formed on the other surface 111b and the lateral surface 111c of the metal layer 111 of the base substrate 110 and/or the openings 140.

The metal layer 111, which is the foundation of the base substrate 110, functions to transfer heat generated from a device 160 to the heat sink layer 120 so that such heat is dissipated to the air.

Because the metal layer 111 is made of a metal, superior heat dissipation effects may be manifested. Furthermore, the metal layer 111 made of a metal is stronger than a core layer made of a typical resin and thus may be greatly resistant to warpage. In order to maximize the heat dissipation effects, the metal layer 111 may include a metal having high thermal conductivity, such as aluminum (Al), nickel (Ni), magnesium (Mg), titanium (Ti), zinc (Zn), tantalum (Ta), or alloys thereof.

The insulating layer 112, which is formed on one surface 111a of the metal layer 111, functions to insulate the metal layer 111 and the circuit layer 113 from each other so that the circuit layer 113 does not short out the metal layer 111.

The insulating layer 112 may include a composite polymeric resin typically used as an interlayer insulating material, such as a prepreg (PPG), an Ajinomoto build-up film (ABF) and so on. Also, in order to improve heat dissipation effects of the insulating layer 112, the insulating layer 112 may be formed by mixing an epoxy-based resin such as FR-4 or bismaleimide triazine (BT) with a ceramic filler. Also, in order to maximize the heat dissipation effects of the insulating layer 112, the insulating layer 112 may be formed by anodizing the metal layer 111. As such, in the case where the metal layer 111 is composed of a metal including Al, the insulating layer 112 may include alumina (Al₂O₃) resulting from anodizing such a metal layer 111. In the case where the insulating layer 112 is formed using anodizing treatment, in particular, in the case where the insulating layer 112 is formed by anodizing Al, heat dissipation effects are increased, and thus there is no need to form a comparatively thick metal layer 111 and thereby the thickness of the heat-dissipating substrate 100 may be reduced.

The circuit layer 113, which is used to electrically connect the device 160 and the heat-dissipating substrate 100 to each other, is formed on the insulating layer 112.

The circuit layer 113 is directly formed on the insulating layer 112 and may thus promptly transfer heat from the device 160 to the insulating layer 112 and the metal layer 111. Also, the circuit layer 113 may be formed wide in a pad shape, not a wire shape, in order to maximize the heat dissipation effects. The circuit layer 113 which is used to electrically connect the heat-dissipating substrate 100 and the device 160 may be patterned using an electrically conductive metal such as gold, silver, copper, nickel or the like. On the other hand, the circuit layer 113 may further include a seed layer (not shown).

The heat sink layer 120, which is formed on the other surface 111b of the base substrate 110, receives heat, which was generated from the device 160, from the metal layer 111 and then dissipates such heat to the outside.

Because the heat sink layer 120 receives heat from the metal layer 111 and then dissipates such heat to the outside, it may be made of a metal having high thermal conductivity, for example, copper (Cu), Al or the like. Furthermore, a plurality of protrusions may be formed on the surface of the heat sink layer 120 opposite the surface in contact with the metal layer 111 so that heat may be efficiently dissipated. In the case where the heat sink layer 120 is formed in the above shape, the surface area of the heat sink layer 120 is enlarged to thus increase the area in contact with air, thereby increasing the amount of heat dissipated to the outside for the same time period.

The connectors 130, which are used to connect the base substrate and the heat sink layer 120 to each other, are inserted via the openings 140 formed in the base substrate 110.

The connectors 130 which connect the base substrate 110 and the heat sink layer 120 to each other may include for example a metal screw for holding parts together. Furthermore, the connectors 130 pass through the openings 140 of the base substrate 110 and are fitted in the recesses 121 of the heat sink layer 120 so that the base substrate 110 and the heat sink layer 120 may be securely held together.

The openings 140, which are spaces into which the connectors 130 are inserted, are formed in the direction of thickness of the base substrate 110. In the case where the connectors 130 are a metal screw, the openings 140 may be provided in the form of a hole the inner surface of which is formed in a female screw shape.

The anodized layer 150, which is formed by anodizing the metal layer 111, may be formed on the other surface 111b and/or the lateral surface 111c of the metal layer 111.

Specifically, in the case where the anodized layer 150 is formed on the other surface 111b of the metal layer 111, namely, at the interface between the metal layer 111 and the heat sink layer 120 in contact with each other, the metal layer 111 may be prevented from being electrically connected to the heat sink layer 120. Thus, static electricity generated from the heat sink layer 120 may be prevented from being transferred to the metal layer 111 and/or the base substrate 110, and voltage shock which is applied to the metal layer 111 to thus deteriorate performance of the device 160 may be reduced. Furthermore, in the case where the anodized layer 150 is formed on the lateral surface 111c of the metal layer 111, the metal layer 111 and/or the device 160 may be protected from free electrons in the air occurring due to static electricity or voltage shock or from free electrons rebounding from the heat sink layer 120.

Because the anodized layer 150 has higher thermal conductivity than the other insulating members, heat may be efficiently exchanged between the metal layer 111 and the heat sink layer 120 despite the anodized layer 150 being formed on the other surface of the metal layer 111. Also, in the case where the metal layer 111 is made of a metal including Al, the anodized layer 150 may include alumina resulting from anodizing Al. In this case, the heat exchange rate may be further increased.

The anodized layer 150 may also be formed on the inner surface of the openings 140 formed in the base substrate 110. In the case where a metal screw is used as the connectors 130, the metal layer 111 may short out the heat sink layer 120 via the connectors 130. Thus, the anodized layer 150 may also be formed on the inner surface of the openings 140, so that the metal layer 111 may be protected from the heat sink layer 120 or external electrons, static electricity and so on.

The device 160, which is mounted on the base substrate 110, may be electrically connected to the base substrate 110 via the circuit layer 113.

The device 160 may include for example a semiconductor device, a passive device, an active device and so on. As the device 160, any device which generates heat in a large amount may be used. For example, an insulated gate bipolar transistor (IGBT) or a diode may be utilized, particularly favored being an LED package. On the other hand, heat generated from the device 160 may pass sequentially through the insulating layer 112, the metal layer 111 and the heat sink layer 120 and may then be dissipated to the air.

Method of Manufacturing Heat-Dissipating Substrate

FIGS. 2 to 6 show a process of manufacturing a heat-dissipating substrate 100a according to a first embodiment of the present invention. With reference to these drawings, the method of manufacturing the heat-dissipating substrate 100a according to the first embodiment of the present invention is described below.

As shown in FIG. 2, an insulating layer 112 is formed on one surface 111a of a metal layer 111 and a circuit layer 113 is formed on the insulating layer 112, thus preparing a base substrate 110.

The insulating layer 112 may be formed by anodizing the metal layer 111 or by mixing epoxy with a ceramic filler. Specifically, in the case where the insulating layer 112 is formed using anodizing treatment, the metal layer 111 is connected to the anode of a DC power source and is immersed in an acidic solution (the electrolytic solution), thereby obtaining the insulating layer 112 including the anodized layer formed on the surface of the metal layer 111. For example, in the case where the metal layer 111 includes Al, the surface of the metal layer 111 reacts with the electrolytic solution (acidic solution), so that Al ions (Al³⁺) are formed at the boundary surface therebetween. The current density is concentrated on the surface of the metal layer 111 due to voltage applied to the metal layer 111, thus generating local heat, and more Al ions are formed by such heat. As a result, a plurality of recesses is formed on the surface of the metal layer 111, and oxygen ions (O²) are moved into the recesses by the force of an electric field and thus react with the electrolytic Al ions, thereby forming the insulating layer 112 including the alumina layer.

The circuit layer 113 may be formed on the insulating layer 112 using a known process, for example, a semi-additive process, a subtractive process, or an additive process.

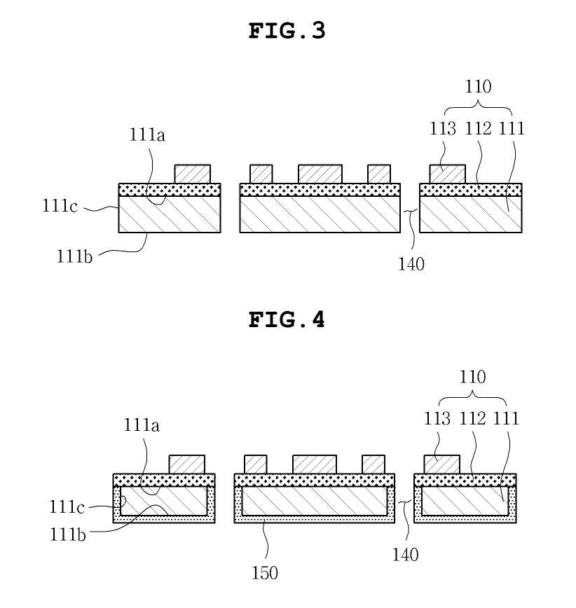

Next, as shown in FIG. 3, openings 140 are formed in the base substrate 110.

The openings 140 are formed in the direction of thickness of the base substrate 110 to have a size adapted to insert connectors 130 therein. For example, in the case where the connectors 130 are a metal screw for holding parts together, the openings 140 may be provided in the form of a hole the inner surface of which may be formed in a female screw shape. Also, the openings 140 may be formed using for example drilling.

Next, as shown in FIG. 4, an anodized layer 150 is formed on the other surface 111b and the lateral surface 111c of the base substrate 110 and/or the openings 140.

The anodized layer 150 may be formed by anodizing the metal layer 111. The anodized layer 150 may be formed not only on the other surface 111b and/or the lateral surface 111c of the base substrate 110, but also on the inner surface of the openings 140.

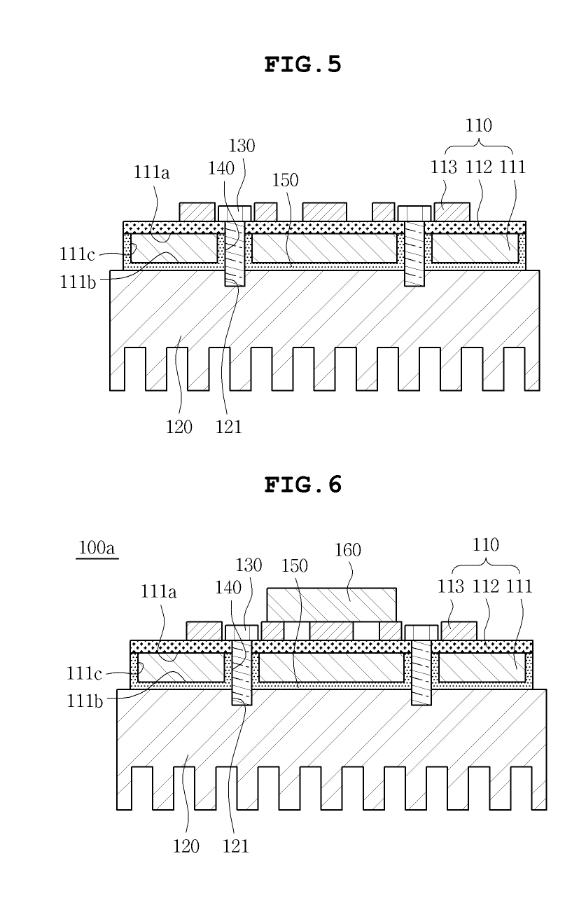

Next, as shown in FIG. 5, the connectors 130 are inserted into the openings 140, so that the heat sink layer 120 is connected to the other surface 111b of the metal layer 111.

The connectors 130 having a size corresponding to that of the openings 140 may be used, and may include any means such as a metal screw as long as they are inserted into the openings 140 of the base substrate 110 so that the base substrate 110 and the heat sink layer 120 are connected to each other. The connectors 130 may be fitted in the recesses 121 of the heat sink layer 120 through the openings 140 of the base substrate 110.

Next, as shown in FIG. 6, a device 160 is mounted on the base substrate 110.

Although connecting the heat sink layer 120 followed by mounting the device 160 have been described with respect to the present embodiment, these two actions may be carried out in the order of first mounting the device 160 and then connecting the heat sink layer 120. This latter order should also be incorporated into the scope of the present invention.

The heat-dissipating substrate 100a according to the first embodiment of the present invention as shown in FIG. 6 is manufactured using the above manufacturing process.

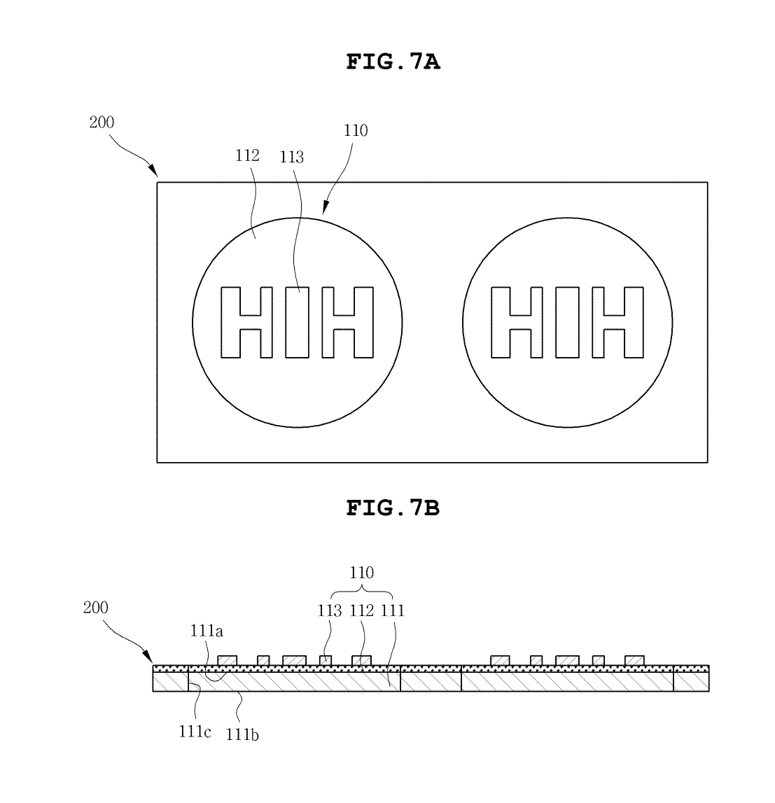

FIGS. 7A and 7B to 11A and 11B and FIGS. 12 and 13 show a process of manufacturing a heat-dissipating substrate 100b according to a second embodiment of the present invention. With reference to these drawings, the method of manufacturing the heat-dissipating substrate 100b according to the second embodiment of the present invention is described below. The constituents which are the same as or corresponding to those of the first embodiment are designated by the same reference numerals, and the description which overlaps the description of the first embodiment is omitted.

As shown in FIGS. 7A and 7B, prepared is a substrate strip 200 including a plurality of base substrates 110 including a metal layer 111, an insulating layer 112 formed on one surface 111a of the metal layer 111, and a circuit layer 113 formed on the insulating layer 112.

In the case where a plurality of base substrates 110 is manufactured in a single substrate strip 200, the formation of the metal layer 111, the insulating layer 112 and the circuit layer 113 included in the plurality of base substrates 110 may be performed once, thus reducing the process time and cost. Although FIG. 7A illustrates the formation of two circular base substrates 110 on the substrate strip 200, the base substrates 110 may have various planar shapes depending on the design conditions of products, and the number of base substrates 110 included in the substrate strip 200 is not limited thereto.

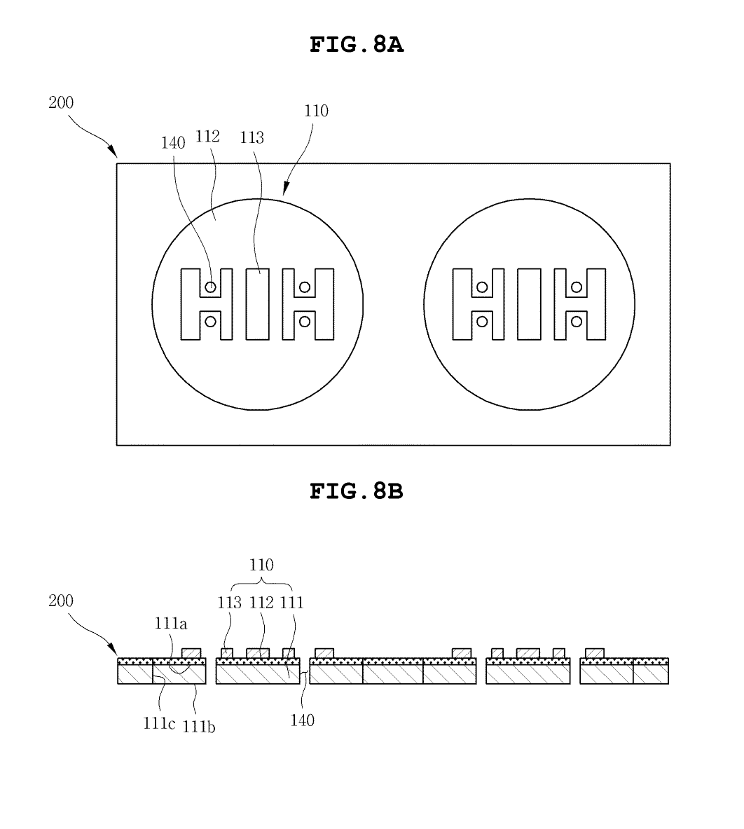

Next, as shown in FIGS. 8A and 8B, openings 140 into which connectors 130 for connecting a heat sink layer 120 to the base substrate 110 are inserted are formed in the direction of thickness of the base substrate 110.

There may be one or a plurality of openings 140 in each of the base substrates 110.

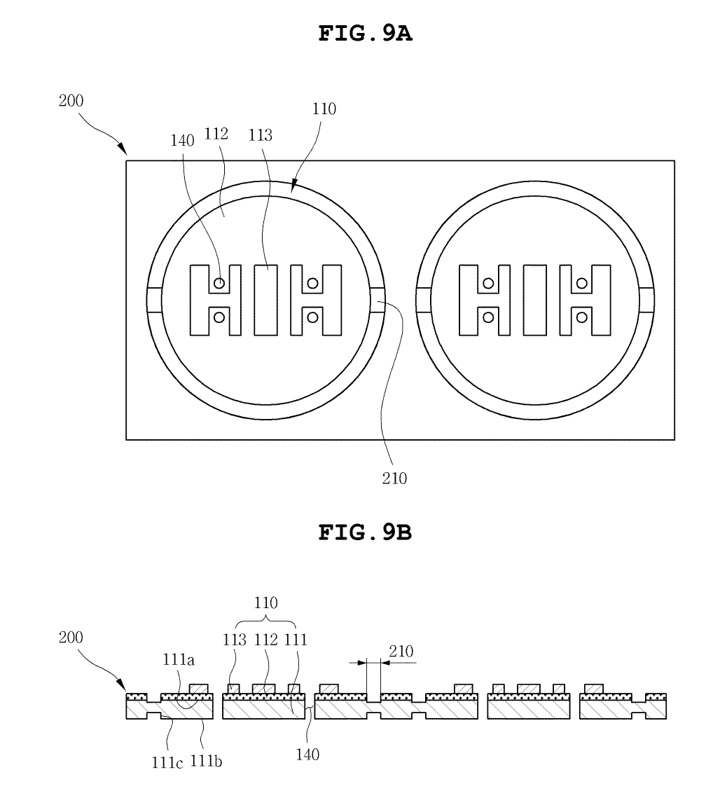

Next, as shown in FIGS. 9A and 9B, the substrate strip 200 is partially cut to prepare a plurality of singularized base substrates 110.

The substrate strip 200 may be cut so as to obtain individual base substrates 110, with bridges 210 for connecting the substrate strip 200 and the base substrates 110 remaining in place. In the formation of an anodized layer 150 which will be described later, the width of the bridges 210 may be narrower so that the anodized layer 150 may be formed on the area which is as large as possible. As such, it is noted that the width of the bridges adapted to hold the base substrates 110 to the substrate strip 200 is maintained. The cutting of the base substrates 110 may be carried out using for example a router- or press-based process.

Furthermore, a V-cut process may be performed on upper and lower portions of the bridges 210 so that the base substrates 110 are easily separated from the substrate strip 200. Specifically, trenches may be formed on the upper and lower portions of the bridges 210 using for example a blade, except for portions of the bridges 210.

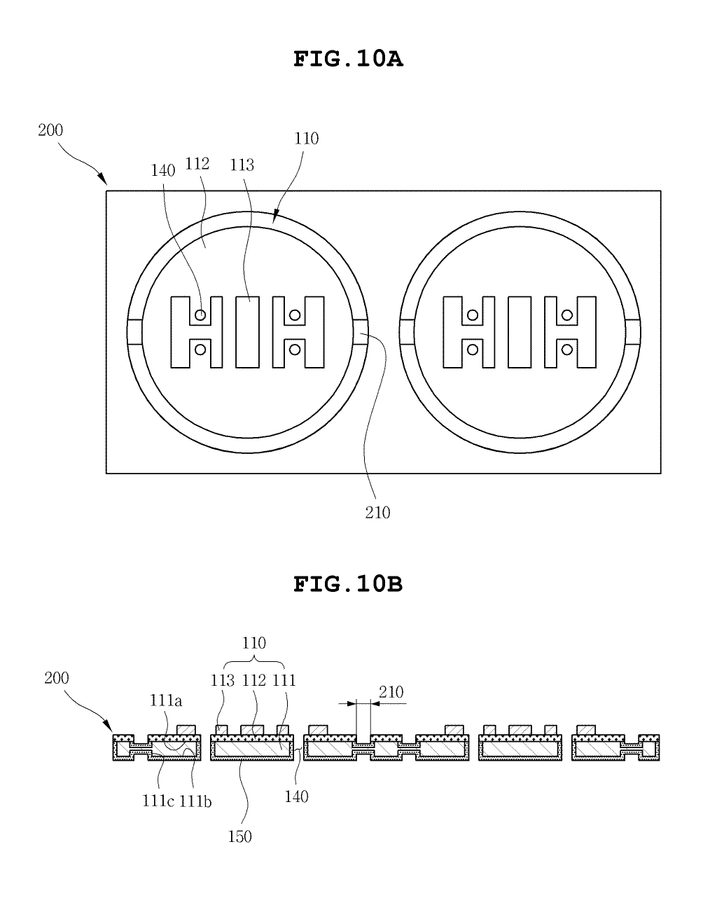

Next, as shown in FIGS. 10A and 10B, the anodized layer 150 is formed on the other surface 111b and the lateral surface 111c of the metal layer 111 of the base substrates 110 included in the substrate strip 200 and/or the inner surface of the openings 140.

Because the base substrates 110 are connected to the substrate strip 200 via the bridges 210, the formation of the anodized layer 150 may be performed once on the entire substrate strip 200, thus making the process convenient. Specifically, when the entire substrate strip 200 is immersed in an electrolytic solution, the anodized layer 150 may be formed on the plurality of base substrates 110, and thus the manufacturing time and cost may be reduced. Furthermore, in the case where the anodized layer 150 is formed on the lateral surface 111c of the metal layer 111, the region where the bridges 210 are formed cannot be formed into the anodized layer 150, and thus the width of the bridges 210 may be designed as narrow as possible.

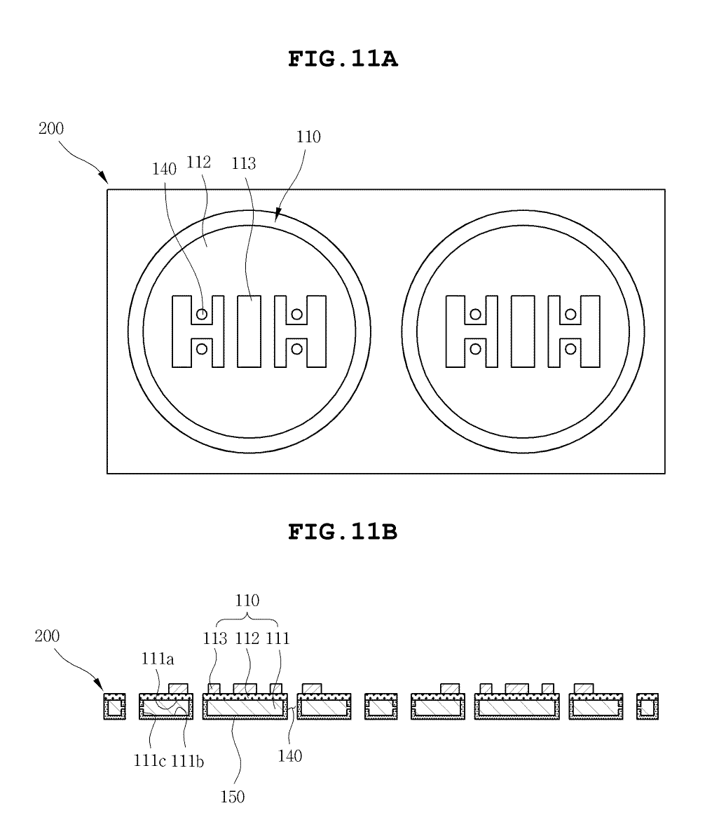

Next, as shown in FIGS. 11A and 11B, the bridges 210 are removed, and the base substrates 110 are individually separated from the substrate strip 200.

As the bridges 210 are removed, the base substrates 110 are not connected to the substrate strip 200 over the entire region, and thus may be separated from the substrate strip 200. The bridges 210 may be removed using for example a router- or press-based process. In the case where the bridges have a narrow width, they may be removed using drilling.

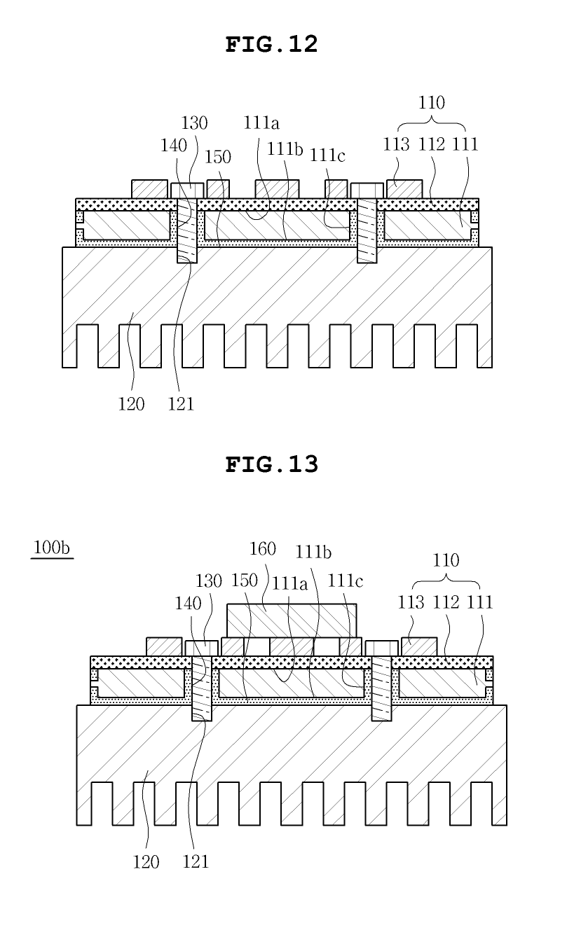

Next, as shown in FIGS. 12 and 13, in individual base substrates 110, the connectors 130 are inserted into the openings 140, whereby the heat sink layer 120 is connected to the other surface 111b of the metal layer 111, after which a device 160 is mounted on the base substrate 110.

As such, the mounting of the device 160 and then the connection of the heat sink layer 120 are possible.

The heat-dissipating substrate 100b according to the second embodiment of the present invention as shown in FIG. 13 is manufactured using the above manufacturing process.

As described hereinbefore, the present invention provides a heat-dissipating substrate and a method of manufacturing the same. According to the present invention, an anodized layer having high thermal conductivity is formed at a contact interface between a metal layer and a heat sink layer, namely, the other surface of the metal layer and/or the lateral surface thereof, thus maintaining heat dissipation properties and preventing the transfer of static electricity or voltage shock to the metal layer and the device.

Also, according to the present invention, in the case where an opening into which a connector for connecting the metal layer and the heat sink layer is inserted is formed, the anodized layer is formed on the opening, thus preventing the electrical connection of the metal layer with the heat sink layer.

Also, according to the present invention, the metal layer includes Al and the insulating layer includes alumina resulting from anodizing the metal layer. Thereby, heat generated from the device can be more quickly dissipated to the outside, and thus the metal layer can be advantageously formed thin.

Also, according to the present invention, the heat-dissipating substrate can be manufactured from a substrate strip including a plurality of base substrates, thus reducing the manufacturing cost and time.

Although the embodiments of the present invention regarding the heat-dissipating substrate and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A heat-dissipating substrate, comprising:
a base substrate comprising a metal layer, an insulating layer formed on one surface of the metal layer, and a circuit layer formed on the insulating layer;
a heat sink layer formed on the other surface of the metal layer;
a connector for connecting the base substrate and the heat sink layer to each other;
an opening formed in a direction of thickness of the base substrate and into which the connector is inserted; and
an anodized layer formed on either or both of the other surface and a lateral surface of the metal layer.

2. The heat-dissipating substrate as set forth in claim 1, wherein the anodized layer is further formed on an inner surface of the opening.

3. The heat-dissipating substrate as set forth in claim 1, wherein the insulating layer is formed by anodizing the metal layer or by mixing epoxy with a ceramic filler.

4. The heat-dissipating substrate as set forth in claim 1, wherein the metal layer comprises aluminum, and the insulating layer comprises alumina formed by anodizing the metal layer.

5. The heat-dissipating substrate as set forth in claim 1, wherein the metal layer comprises aluminum, and the anodized layer comprises alumina formed by anodizing the metal layer.

6. The heat-dissipating substrate as set forth in claim 1, further comprising a device mounted on the base substrate.

7. The heat-dissipating substrate as set forth in claim 6, wherein the device is a light-emitting diode package.

8. A method of manufacturing a heat-dissipating substrate, comprising:
(A) forming an insulating layer on one surface of a metal layer and forming a circuit layer on the insulating layer, thus preparing a base substrate;
(B) forming an opening in a direction of thickness of the base substrate;
(C) forming an anodized layer on either or both of the other surface and a lateral surface of the metal layer; and
(D) inserting a connector into the opening, thus connecting a heat sink layer to the other surface of the metal layer.

9. The method as set forth in claim 8, wherein in (C) the anodized layer is further formed on an inner surface of the opening.

10. The method as set forth in claim 8, wherein in (A) the insulating layer is formed by anodizing the metal layer or by mixing epoxy with a ceramic filler.

11. The method as set forth in claim 8, wherein (A) comprises:
(A1) providing a metal layer comprising aluminum;
(A2) anodizing the metal layer, thus forming an insulating layer comprising alumina on the metal layer; and
(A3) forming a circuit layer on the insulating layer, thus preparing a base substrate.

12. The method as set forth in claim 8, wherein the metal layer comprises aluminum, and the anodized layer comprises alumina formed by anodizing the metal layer.

13. The method as set forth in claim 8, further comprising mounting a device on the base substrate, before or after (D).

14. The method as set forth in claim 13, wherein the device is a light-emitting diode package.

15. A method of manufacturing a heat-dissipating substrate, comprising:
(A) preparing a substrate strip comprising a plurality of base substrates comprising a metal layer, an insulating layer formed on one surface of the metal layer, and a circuit layer formed on the insulating layer;
(B) forming an opening in a direction of thickness of each of the base substrates;
(C) cutting the substrate strip so that each of the base substrates is set off from the substrate strip, except for bridges for connecting the base substrates with the substrate strip;
(D) forming an anodized layer on either or both of the other surface and a lateral surface of the metal layer;
(E) removing the bridges, thus individually separating the base substrates; and
(F) inserting a connector into the opening, thus connecting a heat sink layer to the other surface of the metal layer.

16. The method as set forth in claim 15, wherein in (D) the anodized layer is further formed on an inner surface of the opening.

17. The method as set forth in claim 15, wherein in (A) the insulating layer is formed by anodizing the metal layer or by mixing epoxy with a ceramic filler.

18. The method as set forth in claim 15, further comprising mounting a device on the base substrate, before or after (F).

19. The method as set forth in claim 18, wherein the device is a light-emitting diode package.
